(19) United States
(12) Patent Application Publication
(10) Pub. No.: US 2025/0372405 A1
(43) Pub. Date: Dec. 4, 2025

(54) COVER FOR CIRCUITRY ON SEMICONDUCTOR DEVICES

(71) Applicant: TEXAS INSTRUMENTS INCORPORATED, DALLAS, TX (US)

(72) Inventors: Jeff Jerard A. CANDA, SAN FERNANDO (PH); Lorraine D. QUIJANO, ANGELES (PH)

(21) Appl. No.: 18/679,579

(22) Filed: May 31, 2024

(51) Int. Cl. H01L 21/56; H01L 23/00; H01L 23/31; H01L 25/10

(52) U.S. Cl. CPC H01L 21/565; H01L 23/3107; H01L 23/3157; H01L 24/48; H01L 25/105; H01L 2224/48145; H01L 2224/48245

(57) ABSTRACT

An example method includes providing a substrate that includes a first substrate surface and a die on the first substrate surface, in which the die includes active circuitry within an area at or near an exposed die surface of the die that is spaced from the first substrate surface. The method also includes placing a stencil mask over the first substrate surface, in which the stencil mask includes a stencil opening over at least a portion of the area of the die that includes the active circuitry. The method also includes urging a viscous insulating material through the stencil opening to cover at least the portion of the area of the die that includes the active circuitry.

### BACKGROUND

Some types of packaged semiconductor devices include active circuitry located at or near a surface of the die that can vibrate or move relative to the substrate of the on which they are formed. Some examples of such active circuitry include microelectromechanical systems (MEMS) or resonators, such as sensors, accelerometers, or microactuators. Accordingly, various types of structures have been developed to cover and protect the active circuitry in packaged semiconductor devices.

### SUMMARY

One described example relates to a method that includes providing a substrate that includes a first substrate surface and a die on the first substrate surface, in which the die includes active circuitry within an area at or near an exposed die surface of the die that is spaced from the first substrate surface. The method also includes placing a stencil mask over the first substrate surface, in which the stencil mask includes a stencil opening over at least a portion of the area of the die that includes the active circuitry. The method also includes urging a viscous insulating material through the stencil opening to cover at least the portion of the area of the die that includes the active circuitry.

Another described example provides an apparatus that includes a substrate having opposed first and second substrate surfaces. The apparatus includes a die on the first substrate surface, in which the die includes a die surface spaced apart from the first substrate surface and active circuitry within an area at or near the die surface. The apparatus includes a cover of an insulating material on the area of the die and having a substantially planar surface that is spaced from the die surface. The apparatus also includes a mold compound covering the cover, the die and at least a portion of the substrate.

Yet another described example provides an apparatus that includes a leadframe having a die-receiving surface. A first die is mounted on the die-receiving surface. A second die has first and second die surfaces spaced apart from each other by a die sidewall, in which the second die is mounted on the first die and includes active circuitry within an area at or near a surface of the second die that is spaced apart from the first die by the die sidewall of the second die. A cover of an insulating material covers the area of the second die, the cover has a respective substantially planar surface that is spaced apart from the die surface, and the cover includes a sidewall that extends along at least a portion of the die sidewall of the second die. A mold compound covers the cover, the first die, the second die, and at least a portion of the leadframe.

### BRIEF DESCRIPTION OF THE DRAWINGS

FIG. 1 is a flow diagram illustrating an example method for attaching a wafer cap to a semiconductor device.

FIGS. 2, 3, 4, and 5 are cross-sectional views of an example semiconductor device at various stages of the method of FIG. 1.

FIGS. 6, 7, and 8 are cross-sectional views of another example semiconductor device at various stages of the method of FIG. 1 is a side sectional view illustrating another example wafer cap attachment for a semiconductor device.

FIGS. 9, 10, 11, and 12 are cross-sectional views of another example semiconductor device at various stages of the method of FIG. 1.

FIGS. 13A and 13B are elevation views of the semiconductor device taken along line 13- 13 in FIG. 12.

FIG. 14 is a side sectional view illustrating an example of a packaged semiconductor device.

FIGS. 15 and 16 are elevation views illustrating an example of a multi-device stencil being used to apply protective material onto a plurality of semiconductor devices.

### DETAILED DESCRIPTION

This description relates to a cover for protecting active circuitry on a semiconductor

device. Methods are also described for forming the cover as well as providing a packaged semiconductor device.

In an example, an apparatus includes a substrate a substrate having opposed first and second substrate surfaces. The substrate can be a leadframe or a semiconductor die on which circuitry has been formed. A die can be mounted on the first substrate surface. The die includes a die surface that is spaced apart from the first substrate surface, and active circuitry has been formed within an area of the die at or near the die surface. For example, the active circuitry includes a microelectromechanical system (MEMS) device (e.g., an accelerometer, gyroscope, a microactuator, a piezoelectric device), a resonator (e.g., surface acoustic wave (SAW) resonator, a bulk acoustic wave (BAW) resonator or other dielectric resonator), or other device formed in the die that might vibrate or move relative to the die substrate on which the device is formed (e.g., piezoelectric device). A cover of an insulating material is on and covers at least the area of the die containing the active circuitry. For example, the cover is formed by urging a viscous insulating material through an opening in a stencil mask that is placed over the die. As described herein, the cover is formed in a way so the cover has a substantially planar surface (e.g., a flat top surface of the cover) that is spaced from the die surface. In some examples, the cover has sidewalls that can extend from the planar surface (e.g., top surface) along respective sidewalls of the die and terminate at the first substrate surface. Also, or as an alternative, the cover can encapsulate one or more bond wires coupled between the die and the substrate (e.g., another die or leadframe). The apparatus also includes a mold compound covering the cover, the die, and at least a portion of the substrate to provide a packaged semiconductor device.

The methods and devices described herein can be efficiently implemented as part of or after back-end processing or as part of a packaging workflow. The approach described herein for covering active circuitry on a die further can enable smaller package sizes compared to many existing methods.

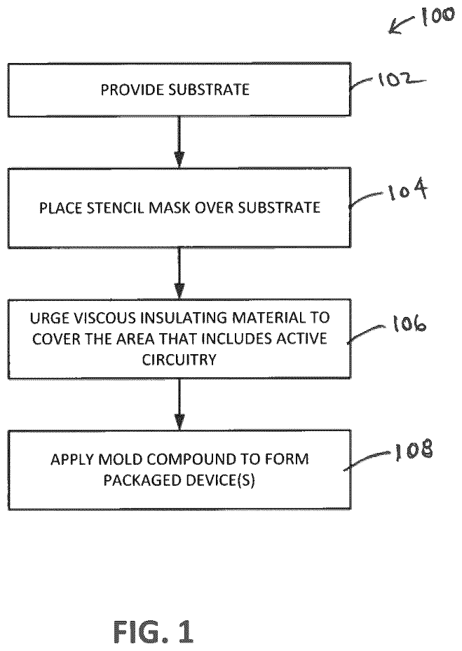

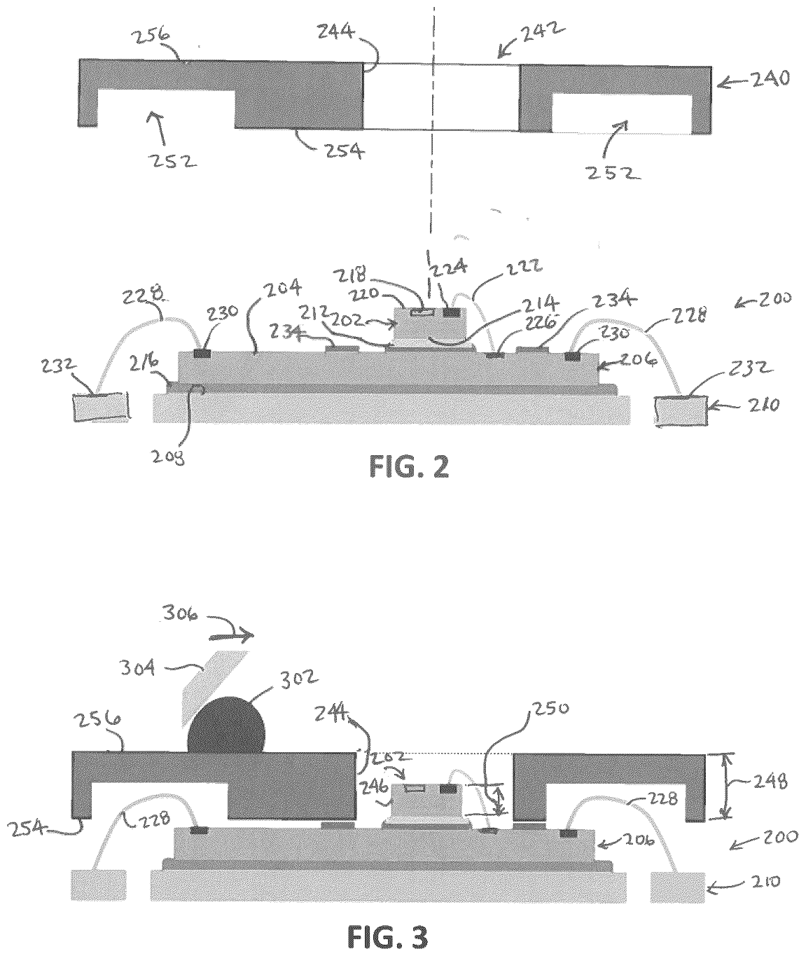

FIG. 1 is a flow diagram illustrating an example method 100 for making a packaged semiconductor device. The method of FIG. I will be described with respect to FIGS. 2-14, which depict examples of semiconductor devices being made at various stages of fabrication. The method 100 is useful to form various types of packaged semiconductor devices, which package type can vary according to the manner in which the package is to be mounted to a substrate (e.g., a printed circuit board). The package type further can include a single-chip integrated circuit (IC) packages, multi-chip packages, or system-on-chip (IC) packages depending on application requirements. In some examples, the method 100 can be implemented as part of a semiconductor device (e.g., die-level) packaging process.

At 102, the method 100 includes providing a substrate having a first substrate surface and a die on the first substrate surface. As described herein, the substrate can include or be implemented as a leadframe or another die. For example, as shown in FIG. 2, a semiconductor device 200 includes a die 202 mounted on a surface 204 of a substrate (e.g., a second die) 206, which is mounted on a surface 208 of a leadframe 210. A layer of a die-attach material (DAM) 212 can couple the surface 204 and a surface 214 of the die 202. Another layer of a DAM 216 can couple the second die 206 to a die-attach area (e.g., a pad) of the leadframe 210. Examples of DAMs that can be implemented to provide each of the DAMs 212, 216 include epoxy, polyimide, benzocyclobutene (BCB), silicone, solder, or other adhesives or combinations thereof. As described herein, the die 202 includes active circuitry 218 within an area located at or near an exposed surface 220 of the die 202 that is spaced from the substrate surface 204 to which the die 202 is mounted. The active circuitry 218 can be implemented as an on-substrate device, such as a microelectromechanical system (MEMS) device, a bulk acoustic wave (BAW) device (e.g., a BAW resonator), a transducer device (e.g., a thin film piezoelectric or sensor), or another type of device.

In the example of FIG. 2, one or more bond wires 222 are coupled between bond pads 224 and 226 on respective surfaces of the dies 202 and 206. Also, one or more additional bond wires 228 can be coupled between bond pads 230 at the surface 220 of the die 206 and leads 232 of the leadframe 210. There can be any number and arrangement of leads 232, bond pads 224, 230 and bond wires 222 and 228 to make the necessary connections to enable the semiconductor device 200 to function according to application and design expectations. Also, the leadframe 210 can include leads or be leadless, which can depend on the type of package being formed. In some examples, the semiconductor device 200 includes a rim (e.g., short wall) 234 that extends outwardly from the surface 204 of the substrate 206 to surround the location where the die 202 is mounted. The rim 234 can be formed from the same or different material as the DAM 212 and be spaced outwardly from the DAM. The rim can be configured to help reduce (or prevent) outgassing of the cover being formed over the die, as described herein. In other examples, the rim can be omitted.

At 104, the method 100 includes placing a stencil mask over the substrate surface. The stencil mask includes an opening having a periphery surrounding the area that includes the active circuitry. For example, as shown in FIGS. 2 and 3, a stencil mask 240 includes an opening 242 having a periphery 244 that is aligned axially with and surrounds the area containing the active circuitry 218 responsive to the placement of the stencil mask. The cross-sectional shape of the opening 242 can be the same or different than a cross-sectional shape of the die 202. For the example where the die 202 has a rectangular cross-sectional shape, and the opening can have a rectangular shape having an area that is larger than the area of the die. Alternatively, the opening can have a circular or polygonal cross-sectional shape that is aligned to circumscribe the die 202 responsive to the placement of the stencil mask 240 on the substrate (e.g., die) 206 on which the die 202 is mounted (at 104), such as shown in FIG. 3. Thus, responsive to the placement of the stencil mask 240 on the substrate (e.g., die) 206, the periphery 244 of the opening 242 defines an interior sidewall of the stencil mask that is spaced outwardly from respective sidewalls 246 of the die 202. In examples where the semiconductor device 200 includes the rim 234, the periphery 244 can align axially with an inner edge of the rim 234, such as shown in FIG. 3. Additionally, as shown in FIG. 3, when placed on the substrate 206 on which the die is mounted, the stencil mask 240 has a thickness 248 (at least along the periphery 244) that is greater than a thickness (e.g., height) 250 of the die 202. Thus, responsive to the stencil mask 240 being placed on the substrate 206 (at 104) with the opening 242 axially aligned with and/or surrounding the die 202, the periphery 244 and exposed surfaces of the substrate 206 and die 202 within the opening (as well as any intervening layers or structures therein) define a mold cavity.

In the example of FIGS. 2 and 3, in which bond wires 222 and 228 have been applied, the stencil mask 240 can include one or more recesses 252 formed in a contact surface 254. A distance between the contact surface 254 and an opposing surface 256 of the stencil can define the thickness 248 of the stencil mask 240. Each of the recesses 252 thus can be arranged and configured to receive respective bond wires 228 therein responsive to the stencil mask 240 being placed on the substrate 206 (at 104). Additionally, in some example embodiments, the interior sidewall of the opening 242 can extend substantially parallel to the central axis of the opening such that the diameter at the surfaces 254 and 256 are substantially the same. Alternatively, the diameter at the contact surface 254 can be slightly (e.g., about 1% to about 10%, such as 5%) larger than the diameter at the opposing surface 256 so that interior sidewall of the opening are angled (e.g., a frusto-conical shape), which can facilitate removal of the stencil mask after urging the viscous insulating material 302 into the opening 242 (at 106). The interior sidewalls of the opening 242 can be straight or curved between the surfaces 254 and 256.

At 106, the method 100 includes urging a viscous insulating material through the stencil opening to cover at least the area of the die that includes the active circuitry. The viscous insulating material can be an insulating material having a viscosity ranging from a low to thixotropic viscosity. Examples of materials that can be used as the viscous insulating material include epoxy materials (e.g., DC7920 epoxy available from Dow Corning), modified epoxy materials, ultra violet cured epoxy materials, polyimides or combinations thereof. Other materials can also be used. For some viscous insulating materials, the viscosity of the viscous insulating material can be set (e.g., by the manufacturer) according to the particular approach used to apply the viscous insulating material into the stencil opening. As a further example, the viscous insulating material has a viscosity ranging from about 3500 cP to about 5500 cP, such as about 4500 cP, and a thixotropic ratio ranging from about 1.5 to about 3.0, such as about 2.3. Other viscosity values can be used in other examples.

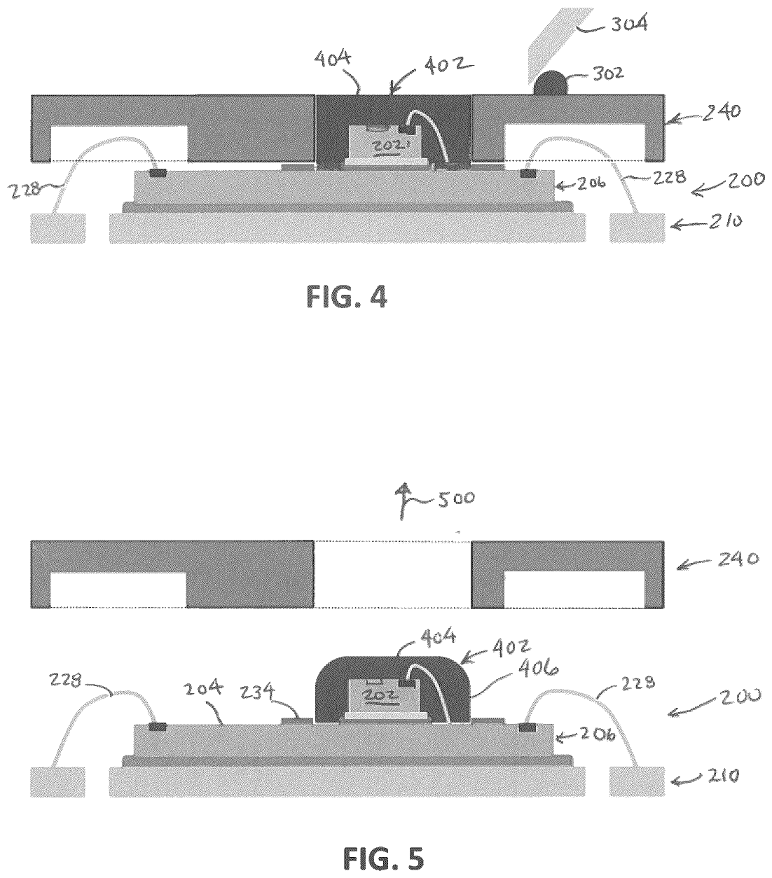

For example, as shown in FIGS. 3 and 4, a volume of a viscous insulating material 302 is urged into the opening to provide a cover 402 that surrounds (e.g., encapsulates) the exposed surfaces of the die 202. The cover 402 can also encapsulate the bond wire 222 coupled between the die 202 and the substrate 206. As shown in the examples of FIGS. 3 and 4, the viscous insulating material 302 can be urged into the opening 242 (at 106) by controlling a spreader 304 to push the viscous insulating material in a direction, shown by arrow 306, across the surface 254 of the stencil and over the opening. The spreader 304 can be implemented as a squeegee, a wiper, a scraper, or other apparatus (or combination of apparatuses) adapted to urge the viscous insulating material 302 into the opening 242. The resulting cover 402 can thus have a substantially planar top surface 404, which can be substantially parallel to the surface 204 of the substrate 206 on which the die 202 is mounted. As another example, the viscous insulating material 302 can be applied into the opening by a nozzle, which can be wiped by a spreader to remove residual viscous insulating material 302 and flatten the top surface of the cover 402. Other mechanisms can be used to urge the viscous insulating material 302 into the opening and form the cover 402 over the area containing the active circuitry 218 of the die 202.

After the viscous insulating material 302 has been urged into the opening (at 106), the stencil mask 240 can be removed from the semiconductor device 200 by moving the stencil mask away from the surface 204 (in the direction of arrow 500), as shown in FIG. 5. As shown in FIG. 5, corners of the cover 402 can settle and thus become rounded (or chamfered). However, the top surface 404 can still maintain at least a central portion that is substantially planar and parallel to the surfaces 204 and 220. Additionally, sidewalls 406 of the cover 402 can be substantially orthogonal to the top surface 204 of the cover. In some examples, after the stencil mask 240 has been removed, the cover 402 can be cured chemically and/or through heating in an oven for a period of time (e.g., at 150 degrees C. for an hour). The particular curing method can vary depending on the properties of the viscous insulating material 302.

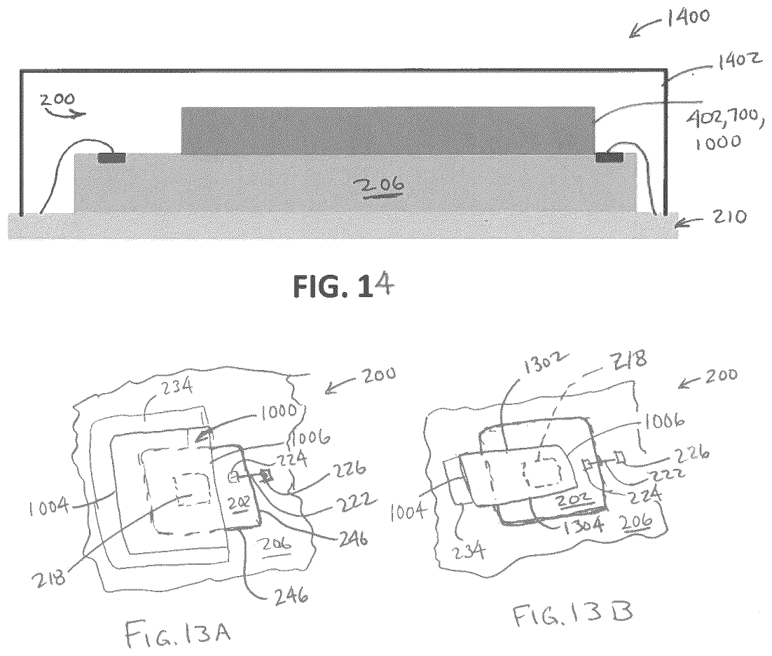

At 108, the method 100 includes applying a mold compound to form a packaged semiconductor device. For example, FIG. 14 depicts an example of packaged semiconductor device 1400 that can be provided by applying a mold compound 1402 (at 108) over the cover, each of the one or more dies, and at least a portion of the leadframe. The mold compound can be formed of one or more insulating materials, such as an organic resin (e.g., epoxy), inorganic resins, and/or other suitable materials.

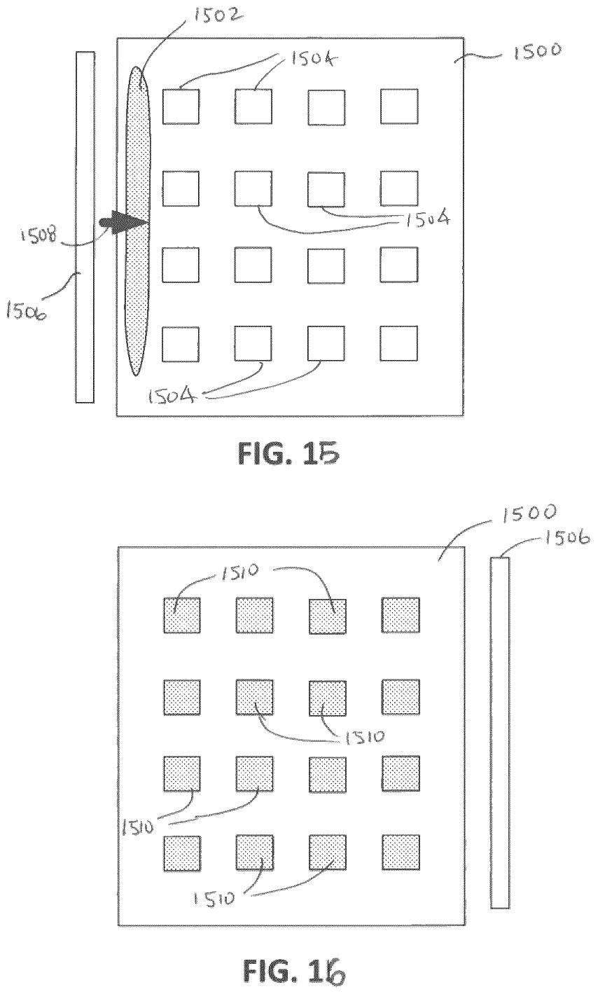

While the examples of FIGS. 2-5 are described with respect to forming a single semiconductor device, in other examples, the method 100 can be implemented to form a plurality of packaged semiconductor devices concurrently or sequentially (see, e.g., FIGS. 15 and 16). For example, the stencil mask 240 includes a plurality of stencil openings arranged and configured to apply a volume of the viscous insulating material into the respective openings and cover at least the area containing active circuitry for each of a plurality of instances of the die. Additionally, or alternatively, the cover can be formed having different configurations to cover different portions of the die containing the active circuitry.

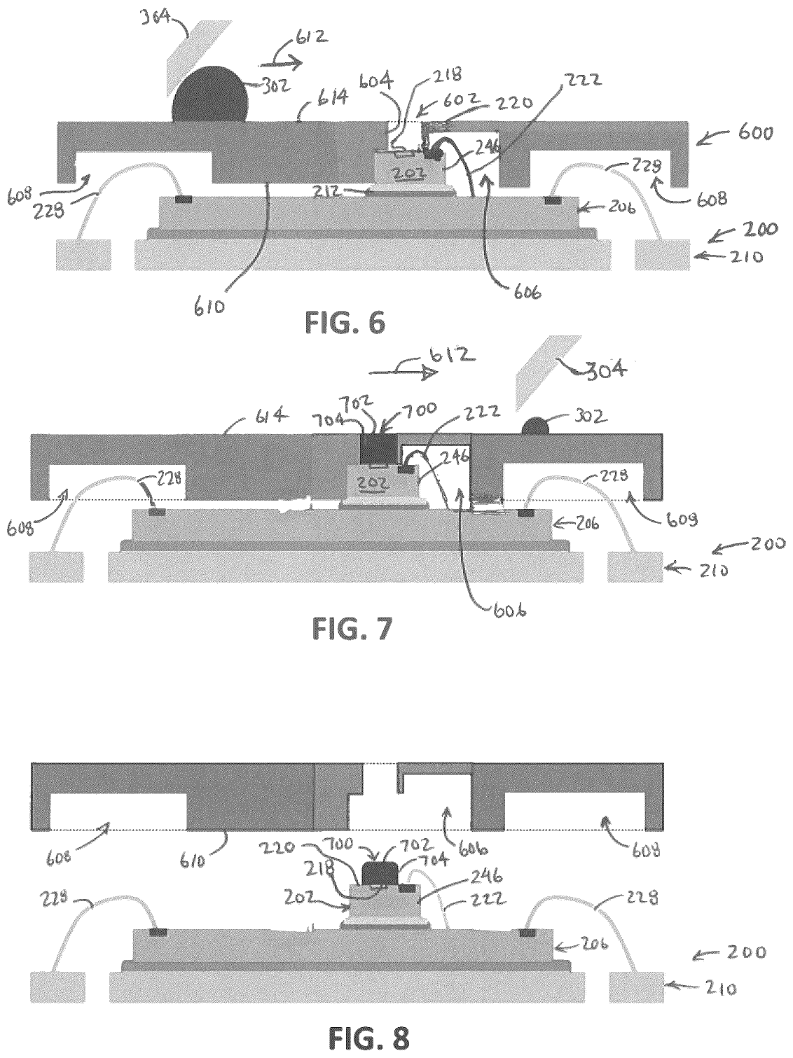

As a further example, FIGS. 6, 7, and 8 are cross-sectional views of another example cover 700 being formed on a semiconductor device 200 at various stages of the method of FIG. 1. The semiconductor device 200 on which the cover 800 is being formed can be the same as described with respect to the examples of FIGS. 1-4. Accordingly, the description of FIGS. 6, 7, and 8 also refers to FIGS. 2-4. FIG. 6 depicts a stencil mask 600 placed (e.g., at 104 of the method 100 of FIG. 1) over a substrate (e.g., base die) 206 to which a die 202 has been mounted by a DAM 212. The stencil mask 600 includes an opening 602 extending through the stencil mask. The opening 602 has an inner periphery 604 configured to align axially with and surround the area that includes the active circuitry 218 at or near the surface 220 of the die 202 responsive to the placement of the stencil mask. In the examples of FIGS. 6, 7, and 8, the inner periphery 604 of the opening 602 is spaced inwardly from the sidewalls 246 of the die at the top surface 220 thereof. Thus, responsive to placing the stencil mask 600 on the semiconductor device 200 with the opening 602 axially aligned with the area that includes the active circuitry 218, as shown in FIG. 6, the periphery 604 and exposed surface 220 of die 202 within the opening 602 define a mold cavity.

In the example of FIGS. 6, 7, and 8, the semiconductor device 200 includes bond wires 222 and 228 before forming the cover 700. Accordingly, the stencil mask 600 includes recesses 606 and 608 formed in a contact surface 610 of the stencil mask. Each of the recess(es) 606 is arranged and configured to receive the bond wire(s) 222 when the stencil mask 600 is placed on the semiconductor device 200 (e.g., at 104). Similarly, each of the recesses 608 is arranged and configured to receive the bond wires 228 when the stencil mask 600 is placed on the semiconductor device 200 (e.g., at 104). In this way, the bond wires 222 and 228 are not impacted by forming the cover 700. Additionally, because the cover does not contact the surface 204 of the substrate 206, the rim 234 on the surface 204 of the substrate (around the die-attach location where the die 202 is mounted) can be omitted. Alternatively, a similar rim, tabs or other retaining mechanism can be formed on the top surface 220 to help retain the cover and/or reduce outgassing of the sidewalls 704 of the cover 700.

As shown in FIGS. 6 and 7, a viscous insulating material 302 can be urged into the opening 602 (e.g., at 106 of FIG. 1). For example, a spreader 304 is adapted to push the viscous insulating material in a direction, shown by arrow 612, across a surface 614 of the stencil mask and over the opening 602 to form the cover 700 in the opening. A top surface 702 of the cover 700 can be substantially flush and parallel with the surface 614 of the stencil mask 600 responsive to the urging of viscous insulating material 302 into the opening by the spreader 304. Sidewalls 704 of the cover 700 can similarly take on a shape of the inner periphery 604 of the opening through the stencil mask 600.

After the viscous insulating material 302 has been urged into the opening (at 106), the stencil mask 600 can be removed from the semiconductor device 200 by moving the stencil mask away from the surface 204 (in the direction of arrow 500), as shown in FIG. 8. In some cases, depending on the viscosity of the viscous insulating material 302, top corners of the cover 700 (between the top surface 702 and sidewalls 704) can settle and become rounded (or chamfered). However, the top surface 702 of the cover 700 can still maintain at least a central portion that is substantially planar and parallel to the surface 220 of the die 202. Additionally, sidewalls 704 of the cover 700 can be substantially orthogonal to the top surface 702 of the cover. In some examples, after the stencil mask 600 has been removed, the cover 700 can be cured chemically and/or thermally through heating in an oven for a period of time (e.g., at 150 degrees C. for an hour). The particular curing method can vary depending on the type and properties of the viscous insulating material 302.

As shown in FIG. 8, the cover 700 includes an outer peripheral edge defined by the intersection of the sidewalls 704 and surface 220 of the die top surface 220 of the die 202 that is spaced inwardly from an outer periphery of the die (at the intersection of the sidewalls 246 and surface 220). Thus, the cover 700 does not cover the sidewalls of the die or extend onto the substrate (e.g., the base die) 206 on which the die 202 is mounted. As a result, when the mold compound is applied at 108, the mold compound extends over and covers the sidewalls of the die. The resulting semiconductor device 200, including the cover 700 can be covered with a mold compound (e.g., at 108 of the method of FIG. 1), such as to provide a packaged device 1400 shown in FIG. 14.

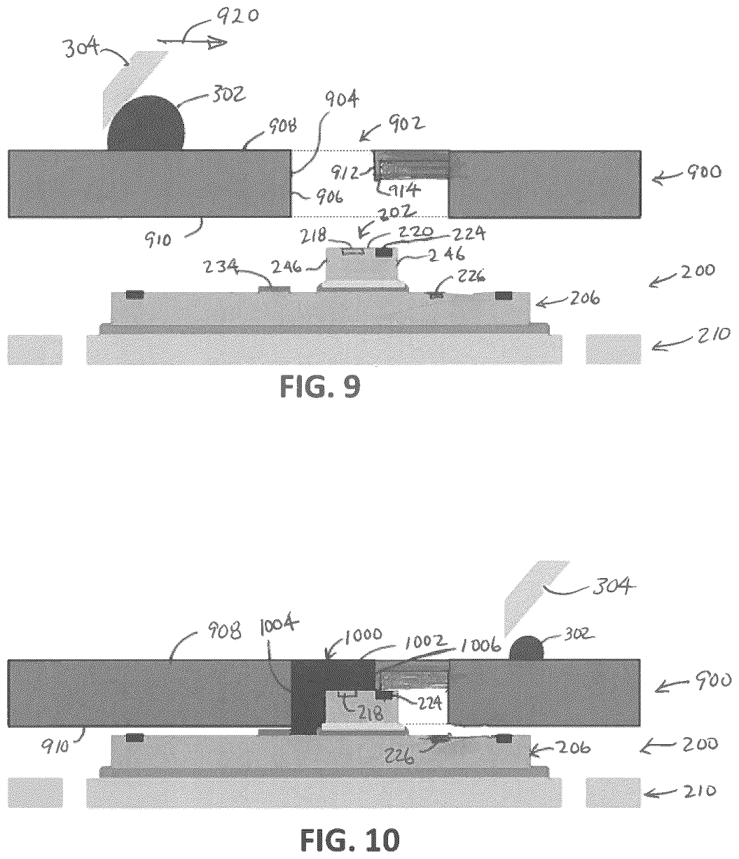

As another example, FIGS. 9, 10, 11, and 12 views of another example cover 1000 being formed on semiconductor device 200 at various parts of the method of FIG. 1. The semiconductor device 200 on which the cover 1000 is being formed can be the same as described with respect to the examples of FIGS. 2-4. Accordingly, the description of FIGS. 9, 10, 11, and 12 also refers to FIGS. 1-4.

FIG. 9 depicts a stencil mask 900 being placed (e.g., at 104 of the method 100 of FIG. 1) over a substrate (e.g., base die) 206 to which a die 202 has been mounted by a DAM 212. The stencil mask 900 includes an opening 902 extending through the stencil mask. The opening 902 has an inner periphery 904 configured to align axially with and surround the area that includes the active circuitry 218 at or near the surface 220 of the die 202 responsive to the placement of the stencil mask (at 104). In the examples of FIGS. 9, 10, 11, and 12, the opening 902 and its inner periphery 904 are configured to form the cover 1000 on a portion of the top surface 220 of the die (at least a portion containing the active circuitry 218) and over a portion of the sidewalls 246. Thus, the cover 1000 can be considered a combination of the covers 402 and 800 because it partially covers the die 202. The amount of coverage can be controlled as a design parameter.

As a further example, the periphery 904 of the opening through stencil mask 900 includes a first wall portion 906 that extends between opposing surfaces 908 and 910 of the stencil mask. The first wall portion 906 is arranged and configured to be spaced outwardly from the sidewall 246 of the die 202 responsive to the stencil mask 900 being placed on the semiconductor device 200 (at 104 of FIG. 1). If a retaining tab or rim 234 is used, the first wall can align with an inner edge of the tab or rim 234, such as shown in FIGS. 9 and 10. The periphery 904 of the opening 902 also includes a second wall portion 912 that extends from the surface 908 to terminate at a distal end 914 located at a position between (e.g., approximately half-way between) the surfaces 908 and 910 of the stencil mask. The length of the second wall portion 912 can be set so that the distal end 914 contacts the surface 220 of the die 202 responsive to the stencil mask 900 being placed on the semiconductor device 200 (at 104 of FIG. 1). Therefore, responsive to placing the stencil mask 900 on the semiconductor device 200 with the opening 902 axially aligned with the area that includes the active circuitry 218, as shown in FIGS. 9 and 10, the periphery 904 (including first and second wall portions 906 and 912), the exposed surfaces 220 and 204 of dies 202 and 206, respectively, within the opening 902 (as well as any intervening layers or structures therein) define a mold cavity for forming the cover 1000.

In the examples of FIGS. 9, 10, 11, and 12, the semiconductor device 200 does not include bond wires 222 and 228 before forming the cover 1000. Accordingly, the stencil mask 600 need not include recesses (e.g., like recesses 252, 606, 608) in the stencil mask. In other examples where the semiconductor device includes bond wires before forming the cover 1000, one or more recesses could be provided in the stencil as described herein with respect to FIGS. 2-8. While the examples of FIGS. 2-8 have been described in the context of forming covers 402, 702 for a semiconductor device 200 already having bond wires 222, 228, in other examples, the covers 402, 700 in such examples could be formed prior to wire bonding such that recesses can be omitted from the stencil masks as described with respect to the examples of FIGS. 9, 10, 11, and 12. Alternatively, recesses can be included on the stencil mask regardless of whether wire bonds are on the semiconductor device at the time of forming the cover(s).

As shown in FIGS. 9 and 10, a viscous insulating material 302 can be urged into the opening 902, such as described herein (e.g., at 106 of FIG. 1). For example, a spreader 304 is adapted to push the viscous insulating material 302 in a direction, shown by arrow 920, across the surface 908 of the stencil mask and over the opening 902 to provide the cover 1000 in the opening. As shown in FIG. 10, a top surface 1002 of the cover 1000 can be substantially flush and coplanar with the surface 908 of the stencil mask 900 responsive to the urging of viscous insulating material 302 into the opening (e.g., by the spreader 304). Sidewalls 704 of the cover 700 can similarly take on a shape of the first and second inner wall portions 906 and 912 of the opening.

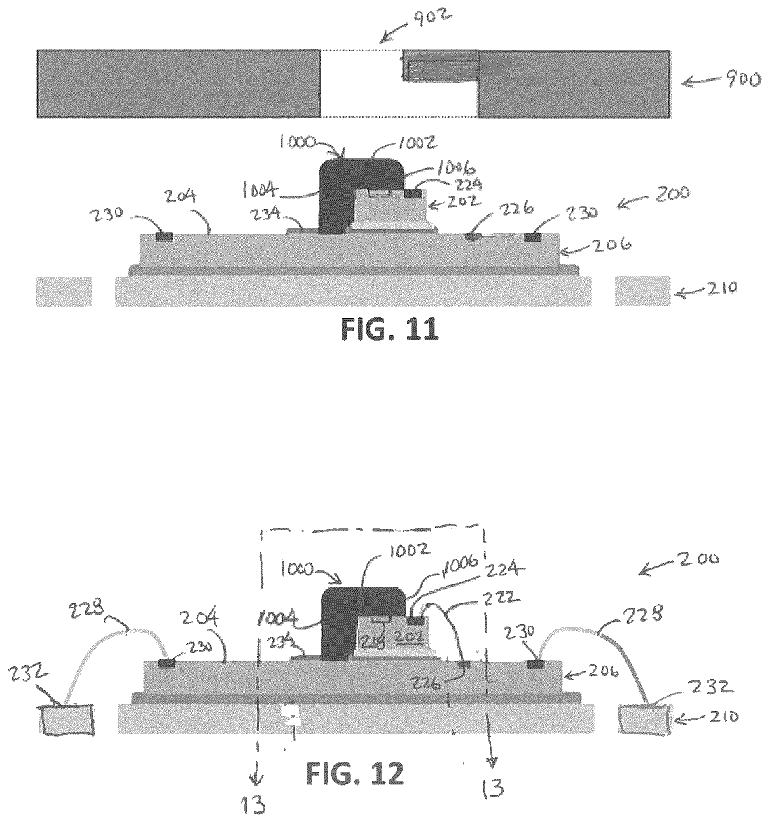

After the viscous insulating material 302 has been urged into the opening (e.g., at 106 of the method 100 of FIG. 1), the stencil mask 900 can be removed from the semiconductor device 200 by moving the stencil mask away from the surface 204 (in the direction of arrow 500), as shown in FIG. 11. In some examples, depending on the viscosity of the viscous insulating material 302, top corners of the cover 1000 (between the top surface 1002 and sidewalls 1004 and 1006) can settle and become rounded (or chamfered). The top surface 1002 can still maintain at least a central portion that is substantially planar and parallel to the surface 220 of the die 202. Additionally, sidewalls 1004 and 1006 of the cover 1000 can be substantially orthogonal to the top surface 1002 of the cover. In some examples, after the stencil mask 900 has been removed, the cover 1000 can be cured chemically and/or thermally through heating in an oven for a period of time, such as described herein.

As shown in FIGS. 11 and 12, a portion of cover 1000 between the sidewall 1004 can extend from the planar surface (e.g., top surface) 1002 along a respective sidewall 246 of the die and terminate at the first substrate surface 204. The opposite sidewall 246 and the bond pads 224 and 226 can remain uncovered by the cover, such as to enable subsequent wire bonding. For example, the second wall portion 912 and the associated distal end 914 are arranged and configured to mask off the bond pads 224 and 226 to prevent the cover 1000 from being formed on the bond pads when urged into the opening 902 while the stencil mask 900 is placed on the semiconductor device 200 (e.g., at 106 of the method of FIG. 1). After the cover is formed on the semiconductor device, which does not include a full set of wire bonds, as shown in FIG. 11, the method 100 can include a wire bonding process to provide respective wire bonds 222 and 228 as shown in FIGS. 12, 13A and 13B. For example, one or more bond wires 222 are coupled between bond pads 224 and 226 on respective surfaces of the dies 202 and 206. Also, one or more additional bond wires 228 are coupled between bond pads 230 at the surface 220 of the die 206 and leads 232 of the leadframe 210. There can be any number and arrangement of leads 232, bond pads 224, 230 and bond wires 222 and 228 to make the necessary connections to enable the semiconductor device 200 to function according to application and design expectations.

FIGS. 13A and 13B are elevation views of different examples of part of the semiconductor device 200 taken along line 13-13 in FIG. 12. In the example of FIG. 13A, the cover 1000 extends along one complete sidewall of the die 202 and along part of two other adjacent sidewalls of the die. The sidewall 1006 defines an edge of the cover 1000 that is spaced apart from the exposed sidewall of the die 202 so the bond pad 224 on the surface 220 remains uncovered while the cover 1000 covers (e.g., completely) the area containing the active circuitry 218.

In the example of FIG. 13B, the cover 1000 covers the area containing the active circuitry 218 and extends over and partially along one sidewall of the die 202, which in the example of FIG. 13B is the sidewall opposite from the sidewall over which the wire bond 222 extends. For example, the cover 1000 has respective edges defined by the sidewalls 1004 and 1006, which are spaced apart from each other by edges 1302 and 1304. The edges 1302 and 1304 can be spaced apart from adjacent sidewalls 246 of the die 202, such that the sidewalls of the die 202 remain uncovered. The edges 1302 and 1304 can be spaced apart from adjacent sidewalls 246 of the die 202 by a distance that can be the same or a different amount than the distance that the cover sidewall 1006 is spaced from the sidewall 246 of the die 202 over which the bond wire extends. The sidewall 1006 further defines an edge of the cover 1000 that is spaced apart from the exposed sidewall of the die 202 so the bond pad 224 on the surface 220 remains uncovered while the cover 1000 covers (e.g., completely) the area containing the active circuitry 218.

The resulting semiconductor device 200, including the cover 1000, can be covered with a mold compound (e.g., at 108 of the method of FIG. 1), such as to provide a packaged device 1400 shown in FIG. 14. Thus, for the example of FIGS. 9-13, the mold compound 1402 extends over and covers exposed sidewalls of the die 202, the cover 1000, the other die 206 and at least a portion of the leadframe 210.

FIGS. 15 and 16 are elevation views illustrating an example of a multi-device stencil mask 1500 to apply a viscous insulating material 1502 onto a plurality of semiconductor devices. As an example, the stencil mask 1500 can be placed over a leadframe sheet (not shown) so that each opening aligns with a respective die containing active circuitry (e.g., at 104 of the method of FIG. 1). The leadframe sheet includes a plurality of leadframes, in which each leadframe includes a die mounted on a substrate, such as shown in the examples of FIGS. 2-13B (e.g., die 202 mounted on a substrate 206). As described herein, the substrate on which the die is mounted can be a leadframe (e.g., leadframe 210) or another die (e.g., base die 206).

The stencil mask 1500 includes a plurality of stencil openings 1504 extending through the mask at spaced apart locations. The stencil openings 1504 are arranged and configured to apply a volume of the viscous insulating material into the respective openings and cover at least the area containing active circuitry for each of a plurality of instances of the die. The stencil openings can be used to form respective covers for instances of dies mounted at respective locations across the leadframe sheet according. The form of the cover can include any of the example covers (e.g., cover 402, 700, 1000) described herein. For example, the cover can encapsulate the top surface and sidewalls of the dies, be applied only on the top surface of the die, or cover the area containing the active circuitry (e.g., a BAW or other device) and extend over a portion of one or more die sidewalls.

After the stencil mask 1500 has been placed on the leadframe sheet, a volume of the viscous insulating material 1502 can be urged over the stencil mask and into the stencil openings 1504 (e.g., at 106 of the method 100 of FIG. 1). The volume of viscous insulating material 1502 can be applied through a nozzle fluidly connected with a source of the viscous insulating material. While the example of FIG. 15 shows the volume of viscous insulating material 1502 along an edge of the stencil mask 1500, in other examples, the viscous insulating material 1502 can be dispensed at one or more other locations, including into the respective openings 1504. For example, a spreader 1506 can be moved (e.g., manually, or automatically controlled) in the direction of arrow 1508 across the stencil mask to push the viscous insulating material into the respective openings, such as shown in FIG. 16. The stencil mask can be removed from the leadframe sheet, and a mold compound can be applied over each of the semiconductor devices on the leadframe sheet, which can then be singulated to provide packaged semiconductor devices, as described herein. In other examples, the respective semiconductor devices can be singulated and packaged separately.

In view of the foregoing examples, the methods and apparatuses (e.g., packaged semiconductor devices) described herein can protect BAW resonators or other active circuitry implemented on a die from external package stress. Additionally, the methods and apparatuses described herein can enable packaged semiconductor devices to be fabricated at smaller package sizes in a streamlined process compared to many existing approaches.

Because the die attach is performed at the die-level, as contrasted to wafer-level processes, the approach described herein can provide a simpler process flow because a complex plasma etch process is not required. The simpler process flow can also reduce the overall processing cost for the on-substrate devices as compared to typically more expensive wafer-level processes.

In this description, the term “couple” may cover connections, communications, or signal paths that enable a functional relationship consistent with this description. For example, if device A generates a signal to control device B to perform an action, then: (a) in a first example, device A is directly coupled to device B; or (b) in a second example, device A is indirectly coupled to device B through intervening component C if intervening component C does not substantially alter the functional relationship between device A and device B, so device B is controlled by device A via the control signal generated by device A.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means within +/-10 percent of the stated value, or, if the value is zero, a reasonable range of values around zero. Modifications are possible in the described examples, and other implementations are possible, within the scope of the claims.

What is claimed is:

1. A method, comprising:
providing a substrate that includes a first substrate surface and a die on the first substrate surface, in which the die includes active circuitry within an area at or near an exposed die surface of the die that is spaced from the first substrate surface;
placing a stencil mask over the first substrate surface, in which the stencil mask includes a stencil opening over at least a portion of the area of the die that includes the active circuitry; and
urging a viscous insulating material through the stencil opening to cover at least the area of the die that includes the active circuitry.

2. The method of claim 1, wherein:
the stencil opening includes a periphery at a contact surface of the stencil mask arranged and configured to surround a periphery of the die responsive to the placement of the stencil mask, and
the insulating material is urged through the stencil opening to cover the exposed die surface and sidewalls of the die with the insulating material.

3. The method of claim 1, wherein the die is a first die and the substrate includes a second die mounted to a leadframe.

4. The method of claim 1, wherein the substrate includes a leadframe.

5. The method of claim 1, wherein:
the substrate comprises a leadframe sheet including a plurality of leadframes and having the first substrate surface,
an instance of the die is mounted on each of the plurality of leadframes, and
the stencil mask includes a plurality of stencil openings, each arranged and configured to expose the area of each instance of the die, which includes respective active circuitry, responsive to the placement of the stencil mask over the leadframe sheet.

6. The method of claim 5, wherein urging the viscous insulating material comprises:
dispensing a volume of the viscous insulating material at a first location on a surface of the stencil; and
urging the viscous insulating material into the respective openings to cover at least the area of each instance of the die that includes the active circuitry thereof.

7. The method of claim 1, wherein urging the viscous insulating material through the stencil opening comprises:
dispensing a volume of the viscous insulating material at a first location on a surface of the stencil; and
pushing the viscous insulating material with a spreader across the surface of the stencil and into the stencil opening.

8. The method of claim 1, wherein the active circuitry comprises a bulk acoustic wave resonator.

9. The method of claim 1, further comprising curing the insulating material.

10. The method of claim 1, further comprising applying a mold compound over the insulating material, the die, and at least the first substrate surface of the substrate to provide a packaged device.

11. An apparatus, comprising:
a substrate having opposing first and second substrate surfaces;
a die on the first substrate surface, in which the die includes a die surface spaced apart from the first substrate surface and active circuitry within an area of the die at or near the die surface;
a cover of an insulating material over the area of the die and having a substantially planar surface that is spaced from the die surface; and
a mold compound covering the cover, the die and at least a portion of the substrate.

12. The apparatus of claim 11, wherein the cover includes a sidewall extending from the first substrate surface to terminate in the substantially planar surface of the cover, and the mold compound extends along an outer surface of the sidewall and over the substantially planar surface of the cover.

13. The apparatus of claim 12, wherein the sidewall of the cover is substantially orthogonal to the substantially planar surface of the cover and extends along at least one side of the substrate.

14. The apparatus of claim 12, wherein:
the die surface is a first die surface, the die has a second die surface opposing and spaced apart from the first die surface by a die sidewall extending between the first and second die surfaces,
the die has a rectangular cross-sectional shape along a virtual plane that extends through the sidewall parallel to the substantially planar surface and includes respective sidewalls extending between the first and second die surfaces, and
the sidewall of the cover has a rectangular cross-sectional shape and surrounds the die.

15. The apparatus of claim 14, further comprising a bond wire coupled between respective pads on the first die surface and the second die surface.

16. The apparatus of claim 15, wherein the cover encapsulates at least a portion of the bond wire.

17. The apparatus of claim 15, wherein the bond wire is external to the cover and the mold compound further covers the bond wire.

18. The apparatus of claim 11, wherein the die is a first die and the substrate is a second die, and the apparatus further comprises:
a leadframe having a die-receiving surface, the second die mounted on the die-receiving surface, and the first die mounted on the second die.

19. The apparatus of claim 11, wherein the cover includes an outer peripheral edge that resides on and is spaced inwardly from a periphery of the die and the cover does not contact the substrate.

20. The apparatus of claim 11, wherein the die comprises an integrated bulk acoustic wave device.

21. An apparatus, comprising:
a leadframe having a die-receiving surface;
a first die mounted on the die-receiving surface;
a second die having first and second die surfaces spaced apart from each other by a die sidewall, in which the second die is mounted on the first die and includes active circuitry within an area at or near a surface of the second die that is spaced apart from the first die by sidewall of the second die;
a cover of an insulating material covering the area of the second die, in which the cover has a respective substantially planar surface that is spaced apart from the die surface, and the cover includes a sidewall extending along at least a portion of the die sidewall of the second die; and
a mold compound covering the cover, the first die, the second die, and at least a portion of the leadframe.

22. The apparatus of claim 21, wherein the sidewall of the cover defines a multi-sided periphery of the cover having a substantially rectangular shape and surrounding and spaced outwardly from respective sidewalls of the second die.

23. The apparatus of claim 21, wherein the insulating material has a low to thixotropic viscosity.

24. The apparatus of claim 21. further comprising a bond wire coupled between the first die and the second die, in which the cover encapsulates the bond wire.
